(19) United States
(12) Patent Application Publication
(10) Pub. No.: US 2026/0341637 A1
(43) Pub. Date: Oct. 29, 2026

(54) DIELECTRIC WINDOW HEATER WITH PLASMA MODULATION

(71) Applicant: Applied Materials, Inc., Santa Clara, CA (US)

(72) Inventors: Zhimin JIANG, Santa Clara, CA (US); Shreeram Jyoti DASH, Newark, CA (US); Jonathan Howard WONG, Santa Clara, CA (US); Tianhong WANG, Sunnyvale, CA (US); Michael NICHOLS, Sunnyvale, CA (US); Yuhui ZHANG, Sunnyvale, CA (US); Daniel Sang BYUN, Campbell, CA (US); Kartik RAMASWAMY, San Jose, CA (US)

(21) Appl. No.: 19/461,125

(22) Filed: Jan. 27, 2026

Related U.S. Application Data
(63) Continuation of application No. PCT/US2025/026202, filed on Apr. 24, 2025.

(51) Int. Cl. H01J 37/32; H05B 1/02

(52) U.S. Cl. CPC H01J 37/32119; H01J 37/32174; H05B 1/0233

(57) ABSTRACT

A circular heating assembly with a diameter that is used to adjust RF floating voltages on the heater assembly. An RF voltage modulation controller may be used to further increase an operational window of the process chamber. In some embodiments, the apparatus may comprise a heater assembly with a circular form and with a lowermost surface in contact with an uppermost surface of a lid of a process chamber. The heater assembly may have four resistive elements separately encased in a conductive material, each forming a quadrant of the heater assembly. In some embodiments, an outer periphery of the heater assembly is electrically isolated from ground of the process chamber by a gap of at least 0.35 inches, and the RF voltage modulation controller is connected to each of the quadrants and ground.

### CROSS-REFERENCE TO RELATED APPLICATIONS

This application is a continuation of International Patent Application serial number PCT/US2025/026202, filed Apr. 24, 2025, which is herein incorporated by reference.

### FIELD

Embodiments of the present principles generally relate to semiconductor processing of semiconductor substrates.

### BACKGROUND

The lid of a semiconductor process chamber encloses the process volume of the chamber while allowing access to the chamber for maintenance tasks. In some chambers, the lid includes a dielectric window that allows inductively coupled plasma power sources to generate plasma inside of the process volume. The dielectric window may also have a heater that facilitates heating the dielectric window to ensure uniform heating within the process volume. The heater may employ resistance heating and be comprised of conductive components. The inventors have observed that the conductive components of the dielectric window heater may interfere with the generation of the plasma within the process volume of the chamber, causing plasma ignition problems.

Accordingly, the inventors have provided methods and apparatus for improving plasma generation within the process volume that incorporate the dielectric window heater.

### SUMMARY

Methods and apparatus for utilizing a dielectric window heater to facilitate modulation of plasma generated within the process volume of a process chamber are provided herein.

In some embodiments, an apparatus for heating a lid of a process chamber may comprise a heater assembly with a circular form and with a lowermost surface in contact with an uppermost surface of the lid of the process chamber where the heater assembly has at least one resistive element encased in a conductive material and is electrically isolated from any ground of the process chamber and an RF voltage modulation controller connected to the heater assembly and a ground where the RF voltage modulation controller is configured to automatically adjust an RF floating voltage level of the heater assembly.

In some embodiments, the apparatus may further include an RF voltage modulation controller that comprises a switch with an OFF state and an ON state and where the RF voltage modulation controller is configured to ground heater assembly in the ON state and to disconnect the heater assembly from ground in the OFF state, an RF voltage modulation controller that comprises a variable capacitor that is configured to be automatically adjusted to control the RF floating voltage level on the heater assembly, an RF voltage modulation controller that comprises a set of solid-state capacitors configured to automatically adjust the RF floating voltage level on the heater assembly and where a total capacitive value of the set of solid-state capacitors can be adjusted by selecting and deselecting different solid-state capacitors within the set of solid-state capacitors, a heater assembly that has a first diameter that is at least 0.7 inches smaller than a second diameter of an uppermost surface of a dielectric window of the lid and where the first diameter is configured to adjust a floating RF voltage level on the heater assembly, a heater assembly that comprises one or more resistive heating circuits, a heater assembly that comprises four resistive heating circuits, each heating circuit encased separately, a heater assembly that comprises four resistive heating circuits where each resistive heating circuit is encased separately and each resistive heating circuit is connected to adjacent resistive heating circuits by a nonconductive bridge to form a unitary heater assembly structure, an RF voltage modulation controller that is connected to a controller and where the controller is configured to regulate the RF floating voltage level on the heater assembly in response to a level of inductive coupling plasma (ICP) power or voltage provided to ICP coils positioned above the heater assembly in the process chamber, a controller that isolates the heater assembly from ground to pulse the RF floating voltage level of the heater assembly when the ICP power or voltage is first turned ON, and/or a controller that isolates the heater assembly from ground to increase the RF floating voltage level of the heater assembly when the ICP power or voltage is first turned ON and gradually reduces the RF floating voltage level over a duration of an ICP power or voltage pulse.

In some embodiments, an apparatus for heating a lid of a process chamber may comprise a heater assembly with a circular form and with a lowermost surface in contact with an uppermost surface of the lid of the process chamber where the heater assembly has four resistive elements separately encased in conductive material, each forming one of four quadrants of the heater assembly and where an outer periphery of the heater assembly is electrically isolated from any ground of the process chamber by a gap of at least 0.35 inches and at least one RF voltage modulation controller connected to each of the quadrants and a ground where the at least one RF voltage modulation controller is configured to automatically adjust an RF floating voltage level of at least one of the quadrants of the heater assembly.

In some embodiments, the apparatus may further include at least one RF voltage modulation controller that comprises a switch with an OFF state and an ON state and where the at least one RF voltage modulation controller is configured to ground one or more of the quadrants of the heater assembly in the ON state and to disconnect from ground one or more of the quadrants of the heater assembly in the OFF state, at least one RF voltage modulation controller that comprises a variable capacitor that is configured to be automatically adjusted to control the RF floating voltage level on at least one quadrant of the heater assembly, at least one RF voltage modulation controller that comprises a set of solid-state capacitors configured to automatically adjust the RF floating voltage level on at least one quadrant of the heater assembly and where a total capacitive value of the set of solid-state capacitors can be adjusted by selecting and deselecting different solid-state capacitors within the set of solid-state capacitors, each quadrant of the heater assembly is connected to adjacent quadrants by a nonconductive bridge to form a unitary heater assembly structure, at least one RF voltage modulation controller that is connected to a controller and where the controller is configured to regulate the RF floating voltage level on at least one quadrant of the heater assembly in response to a level of inductive coupling plasma (ICP) power or voltage provided to ICP coils positioned above the heater assembly in the process chamber, a controller that isolates at least one quadrant from ground to pulse the RF floating voltage level of the at least one quadrant of the heater assembly when the ICP power or voltage is first turned ON, and/or a controller that isolates at least one quadrant of the heater assembly from ground to increase the RF floating voltage level of at least one of the at least one quadrant when the ICP power or voltage is first turned ON and gradually reduces the RF floating voltage level over a duration of an ICP power or voltage pulse.

In some embodiments, a heater assembly for a lid of a process chamber may comprise a circular structure with a lowermost surface configured to contact an uppermost surface of the lid when installed in the process chamber where the circular structure has four resistive elements separately encased in conductive material, each forming a quadrant of the circular structure and an outer periphery of the heater assembly that is configured to be electrically isolated from any ground when installed in the process chamber by a gap of at least 0.35 inches.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of an inductively coupled plasma (ICP) process chamber in accordance with some embodiments of the present principles.

FIG. 2 depicts isometric views of heater assemblies for an ICP process chamber in accordance with some embodiments of the present principles.

FIG. 3 depicts a cross-sectional view of a heater assembly diameter compared to a dielectric window diameter in accordance with some embodiments of the present principles.

FIG. 4 depicts a cross-sectional view of electric fields produced by a floating heater assembly in accordance with some embodiments of the present principles.

FIG. 5 depicts a graph of ICP power or voltage and RF voltage on a floating heater assembly in accordance with some embodiments of the present principles.

FIG. 6 depicts a graph of ICP power or voltage and RF voltage on a floating heater assembly during ICP power or voltage pulsing and plasma striking in accordance with some embodiments of the present principles.

FIG. 7 depicts a cross-sectional view of a process chamber power source with a heater RF voltage modulation controller with variable capacitance and an equivalent circuit in accordance with some embodiments of the present principles.

FIG. 8 depicts an equivalent circuit of a process chamber power source with a heater RF voltage modulation controller with solid-state capacitance in accordance with some embodiments of the present principles.

FIG. 9 is a method of modulating RF floating voltage on a heater assembly of a process chamber in accordance with some embodiments of the present principles.

FIG. 10 depicts a heater RF voltage modulation controller with a grounding switch in accordance with some embodiments of the present principles.

FIG. 11 depicts a top-down view of a single continuous heater element trace of a heater assembly in accordance with some embodiments of the present principles.

FIG. 12 depicts a top-down view of multiple heater element traces of a heater assembly in accordance with some embodiments of the present principles.

FIG. 13 depicts a top-down view of a heater element trace of a heater assembly with RF chokes in accordance with some embodiments of the present principles.

FIG. 14 depicts a top-down view of a heater element trace of a heater assembly with shunt capacitors in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus leverage a dielectric window/lid heater to facilitate plasma generation within the process volume of an inductively coupled plasma (ICP) process chamber. The heater assembly RF voltage is allowed to float relative to the process chamber ground, and RF voltage level modulation of the heater assembly is used to control the electric fields (E-fields) injected into the process volume of the process chamber. The present techniques allow precise control of the amount of capacitive coupling in the process volume to increase striking and restriking plasma performance, increasing the operational process window of the process chamber.

When electrical current is flowed through the coils of an ICP source, the electrical current causes both magnetic fields (H-fields) and electrical fields (E-fields) to radiate from the coils. In general, E-fields in the process volume are undesirable due to detrimental effects that can occur in the process volume such as, but not limited to, oscillating plasma potential, lid sputtering, and E-to-H field transition instabilities, and the like. Conventional ICP process chambers often use grounded Faraday shields to block the E-fields generated by the coils from entering the process volume. However, to strike the plasma, the conventional ICP chambers must retract the Faraday shield to expose the coils to ignite the plasma or have an auxiliary plasma striking source (separate plasma source connected to the process chamber) to generate E-fields to ignite the plasma. Traditional lid heater designs use resistive heaters that are encased in conductive materials to transfer heat to the lid. The heaters are large in diameter and often come in direct contact with the chamber ground or are close to the chamber ground and may be connected to the chamber ground via grounding straps and the like. The grounding of the heater causes the heater to act as a Faraday shield that prevents the ICP coils from capacitively coupling with the plasma in the process volume. Capacitively coupled plasma has lower plasma density than inductively coupled plasma and causes nonuniformity issues in the plasma.

The inventors have observed that low power plasma ignition and complicated pulsed plasma schemes are a trend for advanced logic plasma etching processes as well as other processes. However, the advanced pulsing schemes introduce plasma stability issues which prevents utilizing the complicated pulsing schemes in the process chambers. One considered approach was to increase the striking/re-ignition capability of an ICP source, but inductively coupled plasma is H coupled plasma and has limited ability to strike/re-ignite plasma. In addition, ICP systems have hardware limitations that prevent achieving low power plasma in conjunction with the complicated pulsing schemes, such as, for example, a pulse duty cycle with an OFF time of greater than 10 ms. The inventors have observed that if the OFF stage is longer than 5 ms, re-ignition for the next power ON stage will be problematic. The plasma ignition and re-ignition requires CCP coupling to generate seed electrons for plasma generation and to transition from CCP coupling (low plasma density) to ICP coupling (high plasma density). Thus, the inventors have found that increased CCP coupling is key to obtaining an ICP system that can achieve low power plasma ignition to support the complicated pulsing schemes.

By using the present techniques, the ICP coils capacitively couple to the heater assembly and the heater assembly capacitively couples to the plasma in the process volume of the process chamber in a controllable manner. The capacitive coupling assists in evening out the electromagnetic (EM) fields emitted in the process volume which aids in plasma striking, plasma sustaining, and ICP pulsing profiles and the like, while limiting lid sputtering and other unwanted effects caused by excessive capacitive coupling. The heater voltage level is modulated by allowing the heater assembly to ‘float’ in relation to the chamber ground (the heater assembly is not directly tied to the chamber ground). The diameter of the heater is smaller than with traditional heaters. The heater assembly of the present techniques is designed to increase the distance between the outer perimeter of the heater and the process chamber ground. The heater assembly incorporates an RF voltage level modulation controller to allow for precise control of the effects of the heater's E-field generation during substrate processing.

In some embodiments, the diameter of the heater assembly is at least 0.7″ smaller in diameter than the dielectric window of the lid of the process chamber. In some embodiments, the diameter of the heater assembly is at least 1.0″ smaller in diameter than the dielectric window of the lid of the process chamber. The increased distance of the outer perimeter of the heater assembly to the chamber ground (gap of 0.35″ or greater) is key to allowing the heater to obtain higher floating voltage levels. The heater assembly may have multiple sections with higher numbers of sections allowing for greater uniformity control (e.g., less skew, etc.) in the process volume. In some embodiments, the heater assembly may have four quadrants or sections, each with separate or connected circuits of resistance elements. The four quadrants also allow for separation of the heater assembly from metal gas lines which may be grounded. The separated sections also create discontinuous electrical heater circuit loops that facilitate eliminating eddy current formation in the heater assembly caused by current flowing through the resistance heating elements inside the heater assembly.

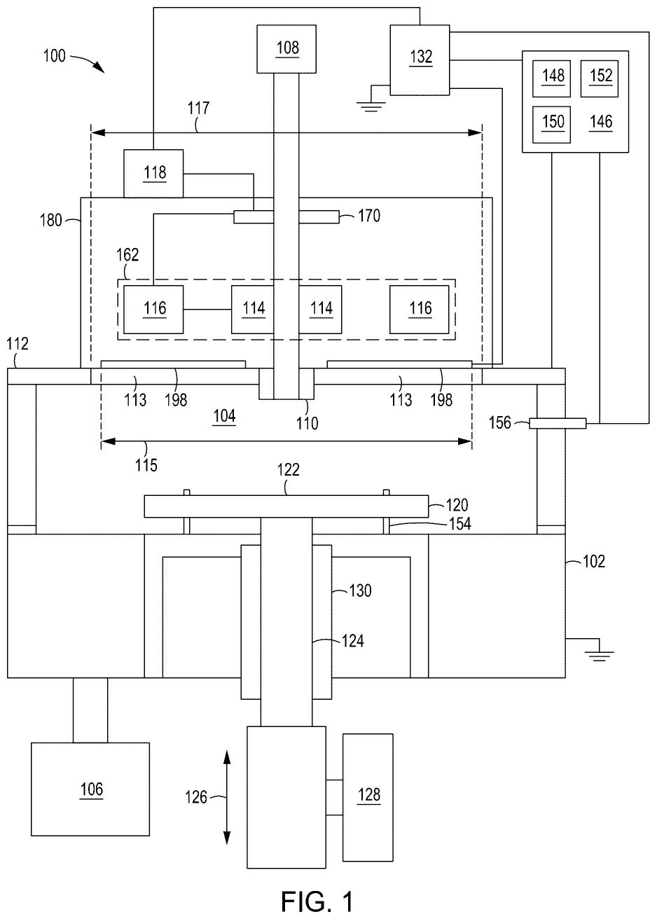

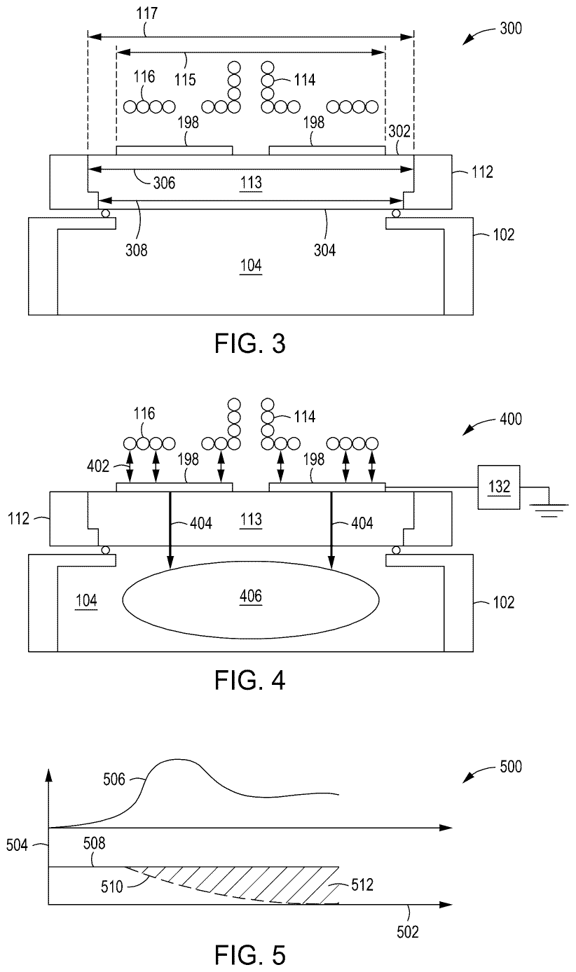

FIG. 1 depicts a cross-sectional view of an example of an ICP chamber 100 in which the present techniques can be used but is not meant to be limiting. The ICP chamber 100 has a lid 112 that may be formed from an aluminum nitride or aluminum oxide-based material and the like and includes a dielectric window 113. A heater assembly 198 for the lid 112 may be positioned at or on the upper surface of the lid 112. In some embodiments, the diameter 115 of the heater assembly 198 is at least 0.7″ smaller in diameter than the diameter 117 of the dielectric window 113 of the lid 112. In some embodiments, the diameter 115 of the heater assembly is at least 1.0″ smaller in diameter than the dielectric window 113 of the lid 112. In instances where an upper surface 302 of the dielectric window 113 may have an upper diameter 306 different from a lower diameter 308 of a lower surface 304 of the dielectric window as depicted in a view 300 of FIG. 3, the diameter 115 of the heater assembly 198 is referenced to the upper diameter 306 of the dielectric window 113 which would be the closest chamber grounding point.

The ICP chamber 100 includes an ICP source assembly 180 which includes a coil assembly 162 and one or more RF plasma sources 118. In some embodiments, the ICP source assembly 180 may be removable from the lid 112. In some embodiments, a hinge or pivot point (not shown) allows the ICP source assembly 180 to tilt up and back to expose the coil assembly 162. The ICP chamber 100 includes chamber walls 102 that enclose a process volume 104 where substrate processing occurs. The ICP chamber 100 also includes a pumping system 106 to control the pressure within the ICP chamber 100 and to expel unwanted gases before, during, or after a substrate has been processed. The pumping system 106 may also include a throttling gate valve to assist in maintaining the pressure within the ICP chamber 100. In some instances, the pumping system 106 may also include a roughing pump for fast pump down and a turbomolecular pump for higher vacuum pressures.

A gas delivery system 108 provides process gases into the process volume 104 through a nozzle 110. The gas delivery system 108 may include showerheads, gas rings, and/or nozzles and the like. In some embodiments, plasma is inductively coupled in the process volume 104 using a coil assembly 162 with dual coil antennas that include one or more inner coils 114 and one or more outer coils 116. In some embodiments, the coil assembly 162 may have inner coils, middle coils (not shown), and outer coils. Plasma coupling power is provided by one or more RF plasma sources 118 with one or more frequencies, waveforms, and/or power levels, etc. If more than one frequency is used, the power may be generated by a single multi-channel RF generator or two separate RF generators that are synchronized. In some embodiments, the one or more RF plasma sources 118 may provide frequencies of approximately 100 kHz to approximately 250 MHz. The supplied RF power may be continuous and/or pulsed. The one or more RF plasma sources 118 may also include one or more RF match networks (not shown) positioned between the one or more RF plasma sources 118 and the coil assembly 162 for adjusting impedances of the power sources to match the load impedance of the ICP chamber 100 for optimal power transfer. In some embodiments, more than two RF sources may be used.

In some embodiments, a power delivery adapter 170 may be connected to the one or more RF plasma sources 118 to distribute power to one or more outer coils 116. The one or more outer coils 116 are electrically connected to the one or more inner coils 114. In the example, which is not meant to be limiting, RF current flows from the one or more RF plasma sources 118 through the one or more outer coils 116 and then into the one or more inner coils 114 and then to the RF ground return. In some embodiments, the one or more RF plasma sources 118 may be first connected to the one or more inner coils 114 and RF current may flow first into the one or more inner coils 114 and then into the one or more outer coils 116 and then to the RF ground return. A heater RF voltage modulation controller 132 is electrically connected to the heater assembly 198 and controls the RF floating voltage level on the heater assembly 198. The heater RF voltage modulation controller 132 may also interface with the controller 146 described below, an optical sensor 156, and/or the one or more RF plasma sources 118 (e.g., sync signal sent to heater RF voltage modulation controller 132 either directly or indirectly, etc.). In some embodiments, the heater RF voltage modulation controller 132 may reside within the controller 146. The heater RF voltage modulation controller 132 may control the RF modulation of the heater based on predetermined profiles (recipes for substrate processing) and/or automatically based on chamber conditions (pressure, temperature, gases, etc.) and/or other feedback on conditions within the process volume 104 (e.g., from optical sensor 156 used to monitor plasma states, etc.). In some embodiments, the heater RF voltage modulation controller 132 may include a central processing unit (CPU), a memory, and a support circuit as described below for controller 146 and/or may reside within controller 146.

A pedestal 120 includes an upper portion 122 with lift pins 154 and a lower portion 124. The pedestal 120 may have vertical motion 126 provided by a lifting assembly 128. A bellows 130 allows the vertical motion 126 to occur without breaking the seal of the process volume 104. The ICP chamber 100 may also include a controller 146. The controller 146 controls the operation of the ICP chamber 100 using a direct control or alternatively, by controlling the computers (or controllers) associated with the ICP chamber 100. In operation, the controller 146 enables data collection and feedback to optimize performance of the ICP chamber 100. In some embodiments, the controller 146 may interact with the heater RF voltage modulation controller 132 that controls the RF voltage level on the heater assembly 198. The controller 146 generally includes a Central Processing Unit (CPU) 148, a memory 150, and a support circuit 152. The CPU 148 may be any form of a general-purpose computer processor that can be used in an industrial setting. The support circuit 152 is conventionally coupled to the CPU 148 and may comprise a cache, clock circuits, input/output subsystems, power supplies, and the like. Software routines, such as used in the methods and/or apparatus as described herein may be stored in the memory 150 and, when executed by the CPU 148, transform the CPU 148 into a specific purpose computer (controller 146). The software routines may also be stored and/or executed by a second controller (not shown) that is located remotely from the ICP chamber 100.

The memory 150 is in the form of computer-readable storage media that contains instructions, when executed by the CPU 148, to facilitate the operation of the semiconductor processes and equipment. The instructions in the memory 150 are in the form of a program product such as a program that implements the apparatus of the present principles. The program code may conform to any one of a number of different programming languages. In one example, the disclosure may be implemented as a program product stored on a computer-readable storage media for use with a computer system. The program(s) of the program product may be used to define functions of the aspects of the present techniques disclosed herein. Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of ICP chamber 100 and/or the heater RF voltage modulation controller 132 as described herein, are aspects of the present principles.

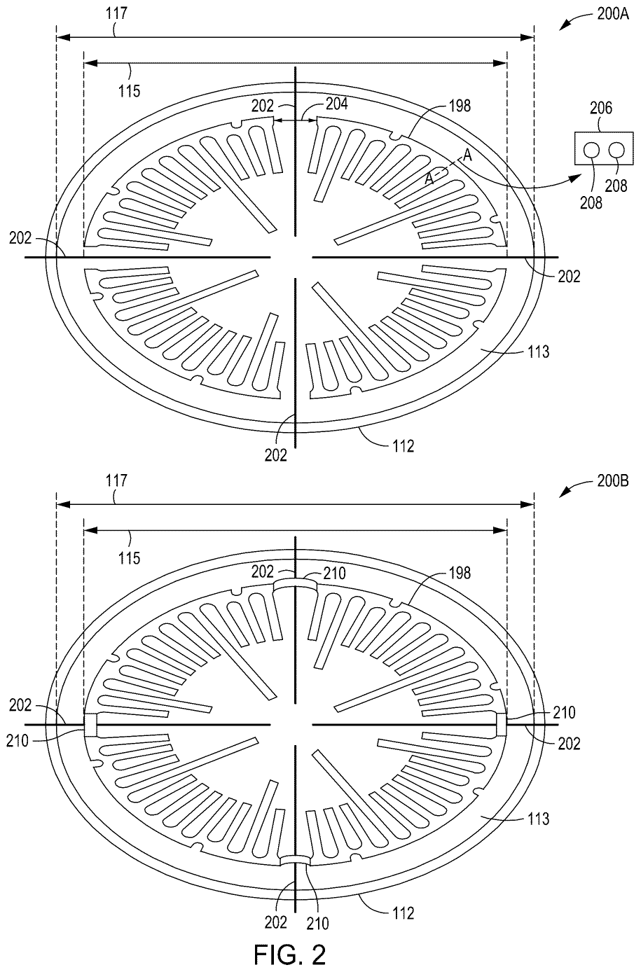

In a view 200A of FIG. 2, is an example where the heater assembly 198 has four sections or quadrants with separate circuits of resistance heating elements. The spacing 204 between sections allows for conductive gas pipes 202 to proceed between the sections with minimal impact on the RF voltage modulation on the heater assembly 198. The separate sections also reduce or eliminate any eddy currents that might be generated in the resistance element 208 inside of the conductive casing 206 of the heater assembly 198. The number of sections can be any number and the example of FIG. 2 is not meant to be limiting. The greater the number, the more precise the RF modulation on the heater assembly 198 and the better the uniformity within the process volume and subsequently the better the uniformity of processes on the substrates. In a view 200B of FIG. 2, bridges 210 are used to join the sections of the heater assembly 198 to form a unitary heater assembly structure. The bridges 210 help to provide rigidity to the heater assembly 198. The bridges 210 can be conductive (e.g., metal, carbon fiber, etc.) or nonconductive (e.g., plastic, etc.). If the bridges 210 are nonconductive, the heater assembly 198 of view 200B has similar operating characteristics of the heater assembly 198 of view 200A. If the bridges 210 are conductive, the heater assembly 198 becomes one loop which may not have the benefits of reduced EM coupling or reduced eddy currents but has the benefit of increased rigidity of the heater assembly. In addition, conductive bridges allow a two-wire connection to the heater assembly 198 for providing heater current to the resistance wires in the heater assembly 198. Nonconductive bridges may require two-wire connections to each of the sections of the heater assembly 198.

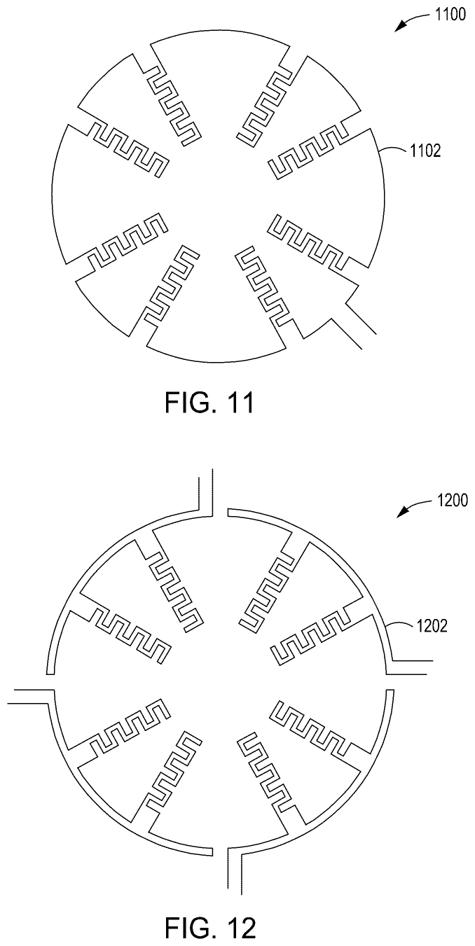

The inventors have found that the internal heater element traces of the resistance element 208 inside of the conductive casing 206 of the heater assembly 198 also impacts the overall RF coupling with the plasma in the process chamber. In some embodiments where the heater assembly 198 is a single unitary structure, a single continuous heater element trace 1102 may be used as depicted in a view 1100 of FIG. 11. The single continuous heater element trace 1102 provides striking and re-ignition benefits, as the induced current from the ICP coils into the heater assembly 198 creates additional voltage on the heater assembly 198 due to the heater element's resistance. However, the heater element's resistance also causes RF power loss in the heater assembly 198. In some embodiments of the heater assembly 198 such as depicted in a view 1200 of FIG. 12, the internal heater element trace 1202 may include multiple traces, one for each section of the heater assembly 198. Any number of traces may be used to form a heater assembly with any number of sections. The use of multiple separated traces assists in breaking any induced current loop induced from the ICP coils to minimize RF power loss in the heater assembly 198. However, striking and re-ignition performance is slightly lower than with the single continuous heater element trace 1102 of FIG. 11.

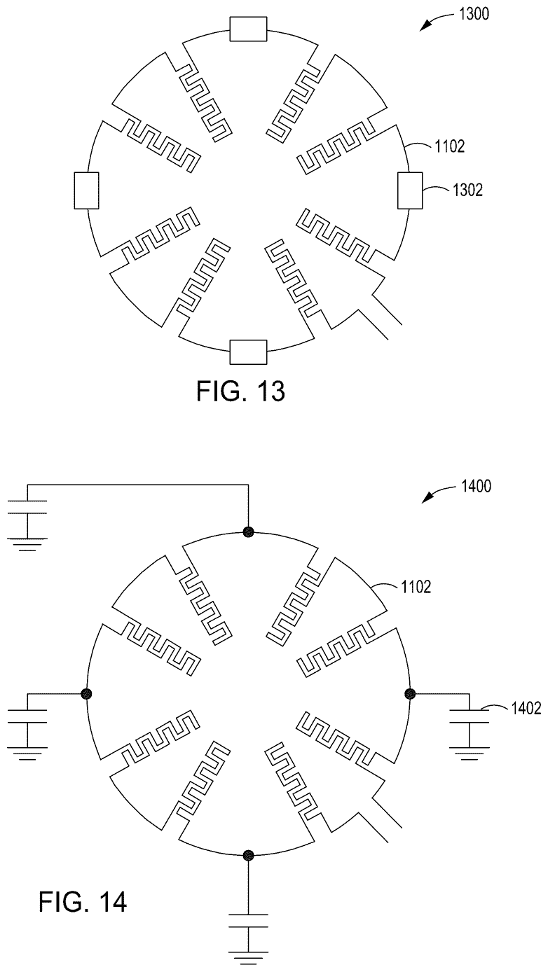

The single continuous heater element trace 1102 of FIG. 11 may be further optimized to stop RF current or to break the RF current loop by adding RF chokes 1302 in electrical series as depicted in a view 1300 of FIG. 13 or shunt capacitors 1402 as depicted in a view 1400 of FIG. 14. Any number of RF chokes 1302 or shunt capacitors 1402 may be used. In some embodiments, the RF chokes may be air core inductors. The RF chokes 1302 add large impedances against RF (high frequency filter) current while still allowing AC current flow (low frequency pass through) to allow the resistance elements of the heater assembly 198 to function as a resistance heater. The added RF chokes keep the striking and re-ignition benefits of the single continuous heater element trace 1102 while minimizing RF power loss. The shunt capacitors 1402 added to the single continuous heater element trace 1102 assist in disrupting the continuity of any RF current loop induced by the ICP coils in the heater assembly 198.

During operation, the ICP coils (the outer coils 116, the inner coils 114) have high voltages. The ICP coils capacitively couple 402 to the heater assembly 198 which is floating as depicted in a view 400 of FIG. 4. The coupling leads to the heater assembly 198 emitting E-fields 404 into the process volume 104 and capacitively coupling with the plasma 406. The emitted E-field from the heater assembly 198 increases the plasma sheath voltage which leads to increased lid sputtering compared to a traditional grounded heater designs. The heater RF voltage modulation controller 132 is used to modulate the RF floating voltage level on the heater assembly 198 to reduce excessive E-field strength that may cause unwanted effects such as lid sputtering and the like. Because the heater RF voltage modulation controller 132 can control the RF floating voltage level, the unwanted effects can be eliminated or reduced while still permitting capacitively coupled plasma to occur in the process volume to gain plasma striking and restriking abilities to increase the chamber's process window over traditional heater designs. In some embodiments, one or more RF floating voltage modulation controllers may be used, and each controller may be connected to one or more of the sections of the heater assembly 198. Using multiple RF floating voltage modulation controllers can enable greater control over the uniformity of the plasma within the process volume of the process chamber. For example, opposite quadrants of the heater assembly 198 can be allowed to float while the other quadrants are grounded, etc. to alter the locations of the E-fields emitted into the process volume. For the sake of brevity, examples herein are depicted using a single RF floating voltage modulation controller but are not meant to be limiting.

A graph 500 of FIG. 5 depicts an ICP initial power or voltage pulse 506 in conjunction with the floating RF floating voltage level 508 of the heater assembly 198. The X-axis 502 is time and the Y-axis 504 is amplitude. If the RF floating voltage level 508 is left at a constant value, excess voltage represented by graph area 512 would cause unwanted lid sputtering as the ICP power or voltage level increased and leveled off. The present techniques allow for control of the RF floating voltage level 508 such that the RF floating voltage level 508 can be deviated (reduced) to adjusted RF floating voltage level 510 to eliminate the excess voltage represented by graph area 512, eliminating the lid sputtering and/or other unwanted effects of the excessive RF floating voltage on the heater assembly 198. In some instances, the floating voltage is not needed for striking plasma with ICP power or voltage. However, the ICP power or voltage may still have a difficult time in initially bringing the plasma density to higher levels. The ICP power or voltage may need the assistance of the CCP coupling from the RF floating voltage on the heater assembly 198 to increase the E-field in the process chamber to generate charged electrons inside of the process volume. The floating RF voltage ignites the charged electrons to form plasma which is then maintained by the ICP power or voltage. In some cases, the RF floating voltage may be bled off slowly so as not to abruptly stop the plasma igniting assistance to allow the ICP power or voltage time to more smoothly transition to sustaining high density plasma.

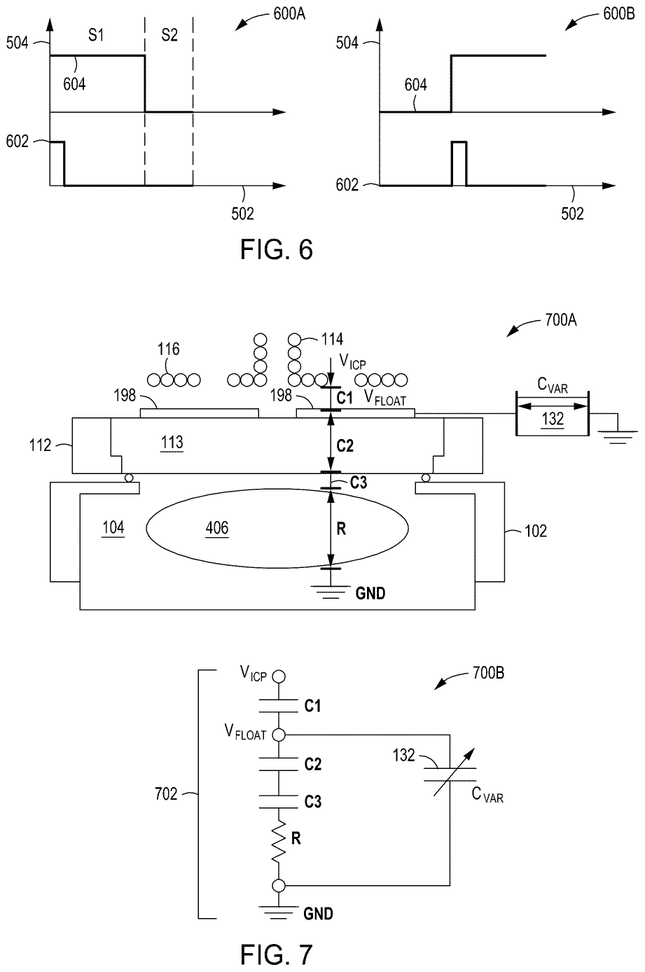

In some instances, the RF floating voltage level on the heater assembly 198 may be controlled based on a pulsing scheme of the ICP power or voltage applied to the ICP coils as depicted in view 600A and view 600B of FIG. 6. In view 600A the floating voltage 602 of the heater assembly 198 is allowed to float when the ICP power or voltage 604 is pulsed and then grounded during the initial stage (S1) of the ICP power or voltage pulse 606. In some embodiments, the switching speed of the heater RF floating voltage may be in the microsecond range for ICP power or voltage pulsing schemes. In some instances, the RF floating voltage level on the heater assembly 198 may be controlled based on assistance needed for striking plasma by the ICP coils as depicted in view 600B of FIG. 6. When the ICP power or voltage 604 transitions from an OFF state to an ON state, the floating voltage 602 can be pulsed to assist with the striking or restriking of the plasma. In some embodiments, the switching speed of the heater RF floating voltage may be in the millisecond range for plasma striking assistance.

Any of the RF floating voltage characteristics of the heater assembly 198 can be adjusted to allow for precise control of the E-fields in the process volume 104. The duration (e.g., continuous wave, pulse, etc.), amplitude (voltage level), and/or voltage envelope (waveform, overall shape over time). The heater RF voltage modulation controller 132 can be used to adjust any of the characteristics of the RF floating voltage on the heater assembly 198. As such, the heater RF voltage modulation controller 132 may be able to switch in the millisecond range down to the microsecond range depending on implementation. In some embodiments as depicted in a view 1000 of FIG. 10, the heater RF voltage modulation controller 132 is a switch 1002 that connects the heater assembly 198 to ground 1004. When the ICP power or voltage is switched to an ON state, the heater RF voltage modulation controller 132 is switched to an open or OFF state to allow the voltage level on the heater assembly 198 to float. When the ICP power or voltage is switched to an OFF state, the heater RF voltage modulation controller 132 is switched to an ON state (switch closed) to ground the heater assembly 198 to the process chamber ground and bleed off the RF voltage from the heater assembly 198. The maximum level of RF floating voltage can be adjusted by decreasing the diameter of the heater assembly 198 (increasing the distance of the heater assembly 198 to the chamber ground) which decreases the capacitance between the heater assembly 198 and the chamber ground. In some embodiments, the heater RF voltage modulation controller 132 can be switched ON (grounding the heater assembly 198) when E-field assistance plasma sustaining is not needed and switched OFF (allowing floating of RF voltage on the heater assembly 198) when lower E-field power is needed for long ICP power or voltage off time pulsing, etc.

The heater RF voltage modulation controller 132, in some embodiments, may comprise a circuit with variable capacitance as depicted in a view 700A and a view 700B of FIG. 7. View 700A depicts the capacitance C1 between the ICP coils and the heater assembly 198, the capacitance C2 between the heater assembly 198 and the plasma sheath, and the capacitance C3 of the plasma sheath/plasma. View 700A also indicates the resistance R of the plasma, the chamber ground, GND, the voltage of the RF voltage of the ICP coils, V_{ICP}, and the RF floating voltage of the heater assembly, V_{FLOAT}. The plasma will also have a slight amount of capacitance which is included as part of C3. View 700B depicts an equivalent circuit 702 including the variable capacitance, C_{VAR} of the heater RF voltage modulation controller 132. Changing the capacitance of C_{VAR} of the heater RF voltage modulation controller 132 changes the floating voltage, V_{FLOAT}, on the heater assembly 198. When a high floating RF voltage is needed, decreasing the capacitance of C_{VAR} of the heater RF voltage modulation controller 132 increases the floating RF voltage, V_{FLOAT}, on the heater assembly 198 which can assist in enabling low power and long OFF time pulsing of the ICP power or voltage. When low floating voltage is needed, increasing the capacitance, C_{VAR} of the heater RF voltage modulation controller 132 increases the capacitive coupling to ground, resulting in less E-field entering the process volume and reducing lid sputtering and the like. In some embodiments, the variable capacitor value change speed may be in the millisecond range due to mechanical control (e.g., servo, etc.) for varying C_{VAR}.

In some embodiments, the heater RF voltage modulation controller 132 may comprise a circuit with an array of switches 806, each controlling one capacitor 808 of an array of capacitors as depicted in a view 800 of FIG. 8. View 800 depicts an equivalent circuit 802 including the capacitor array 804 of the heater RF voltage modulation controller 132. In some embodiments, the capacitor array 804 is a solid-state capacitor array. The use of solid-state capacitor arrays allows the heater RF voltage modulation controller 132 to be of a smaller size compared to the variable capacitor embodiment using a mechanical device to alter the value of the capacitor. The small size has the benefit of being able to easily integrate the capacitor array 804 into existing network boxes and the like (e.g., in RF switching networks, etc.). The capacitor array 804 may have any number of solid-state capacitors with each capacitor having any value of capacitance. The capacitance values of the capacitor array 804 can be adjusted based on chamber type and/or the RF voltage level applied to the ICP coils. For example, the higher the ICP coil voltage, the larger the capacitance that is needed to lower the RF floating voltage on the heater assembly 198 to reduce lid sputtering etc. In some embodiments, the capacitor values of each of the capacitors in the capacitor array 804 may be the same value or differing values. In the example of FIG. 8, four capacitors are used which gives the possibility of 4 factorial combinations or 24 different possible values. For more possible values, a larger number of capacitors can be used. The duration of each of the values selected can also be adjusted, even during a single pulse width to create any type of pulse envelope for the floating voltage on the heater assembly.

The other benefit to using solid-state capacitors is the ability to switch capacitance values much faster than with a variable capacitor using a step motor. In some embodiments, the capacitor value state switching time may be in the microsecond range. The quick switching allows for broader processing windows as the RF floating voltage can be altered much more quickly for pulsing schemes used with the ICP power or voltages. In addition, the RF floating voltage envelope or waveform on the heater assembly can be easily adjusted due to the fast-switching speeds even during pulsing. For example, the capacitor array 804 can start with a large capacitance value and then decrease the capacitance value over time to start with a low RF floating voltage on the heater assembly that increases over time to a high RF floating voltage even during a single pulse. The different RF floating voltage envelopes can be used to precisely control E-field injection into the process volume to aid in plasma ignition and/or plasma sustaining without causing unwanted effects due to excessive E-fields (e.g., lid sputtering, etc.). Different plasma gases can require different levels of E-fields for ignition and sustaining. The present techniques in the embodiments disclosed herein allow for manual and/or automatic adjustments of the E-fields (by controlling the capacitance and the floating RF voltage on the heater assembly) based on ICP power or ICP voltage, gas types, and/or chamber conditions such as pressure and/or temperature and the like.

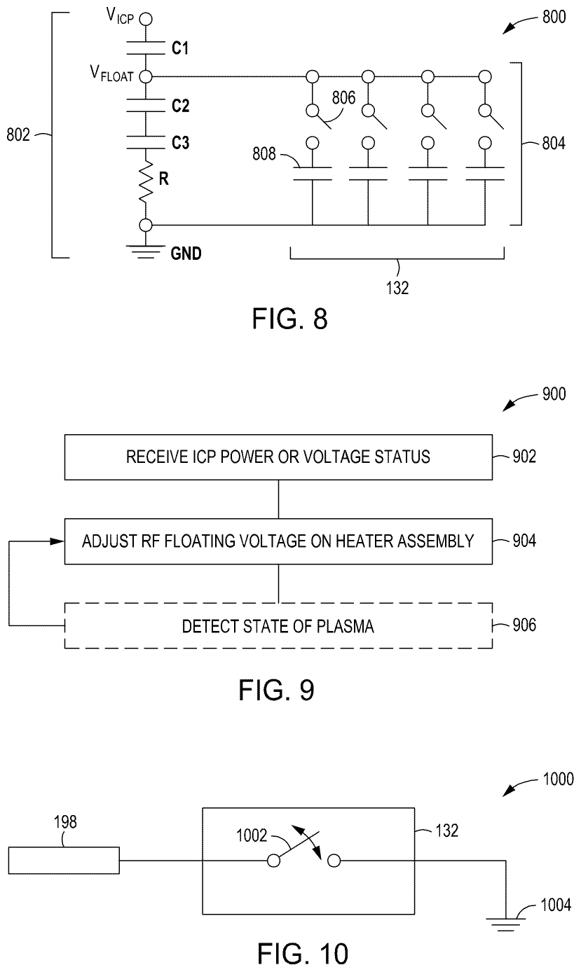

FIG. 9 is a method 900 of adjusting electric fields in a process volume of a process chamber. In block 902, an ICP power or voltage status is received. The ICP power or voltage status may be, for example, a synchronous power signal or other indication that the ICP power or voltage status has changed. For example, the power or voltage status may transition from an OFF state to an ON state. The power or voltage status may include, besides timing, the amplitude and/or duration of a particular state or pulse frequency, pulse width, and the like. In block 904, The RF floating voltage on the heater assembly can then be adjusted based on the ICP power or voltage status. The RF floating voltage can be turned ON, turned OFF, adjusted in duration, adjusted in waveform, and/or adjusted based on an ON or OFF status of the ICP power or voltage and the like. The RF floating voltage can also be adjusted based on chamber pressure, temperature, and/or gases used in the plasma and the like. The RF floating voltage can be adjusted using a heater RF voltage modulation controller 132. In some embodiments, the heater RF voltage modulation controller 132 may adjust RF floating voltage by grounding or ungrounding, by a variable capacitor, and/or by using solid state capacitance and the like. In optional block 906, feedback on the state of the plasma in the process volume and/or other chamber conditions may be used to iteratively adjust the RF floating voltage on the heater assembly. For example, an optical sensor (see, e.g., optical sensor 164 in FIG. 1, etc.) may be used to detect the intensity of the plasma inside of the process volume as an indication as to the state of the plasma and the like.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. An apparatus for heating a lid of a process chamber, comprising:
a heater assembly with a circular form and with a lowermost surface in contact with an uppermost surface of the lid of the process chamber, wherein the heater assembly has at least one resistive element encased in a conductive material and wherein the heater assembly is electrically isolated from any ground of the process chamber; and
an RF voltage modulation controller connected to the heater assembly and a ground, wherein the RF voltage modulation controller is configured to automatically adjust an RF floating voltage level of the heater assembly.

2. The apparatus of claim 1, wherein the RF voltage modulation controller comprises a switch with an OFF state and an ON state and wherein the RF voltage modulation controller is configured to ground heater assembly in the ON state and to disconnect the heater assembly from ground in the OFF state.

3. The apparatus of claim 1, wherein the RF voltage modulation controller comprises a variable capacitor that is configured to be automatically adjusted to control the RF floating voltage level on the heater assembly.

4. The apparatus of claim 1, wherein the RF voltage modulation controller comprises a set of solid-state capacitors configured to automatically adjust the RF floating voltage level on the heater assembly and wherein a total capacitive value of the set of solid-state capacitors can be adjusted by selecting and deselecting different solid-state capacitors within the set of solid-state capacitors.

5. The apparatus of claim 1, wherein the heater assembly has a first diameter that is at least 0.7 inches smaller than a second diameter of an uppermost surface of a dielectric window of the lid and wherein the first diameter is configured to adjust a floating RF voltage level on the heater assembly.

6. The apparatus of claim 1, wherein the heater assembly comprises one or more resistive heating circuits.

7. The apparatus of claim 6, wherein the heater assembly comprises four resistive heating circuits, each heating circuit encased separately.

8. The apparatus of claim 6, wherein the heater assembly comprises four resistive heating circuits, wherein each resistive heating circuit is encased separately and wherein each resistive heating circuit is connected to adjacent resistive heating circuits by a nonconductive bridge to form a unitary heater assembly structure.

9. The apparatus of claim 1, wherein the RF voltage modulation controller is connected to a controller and wherein the controller is configured to regulate the RF floating voltage level on the heater assembly in response to a level of inductive coupling plasma (ICP) power or voltage provided to ICP coils positioned above the heater assembly in the process chamber.

10. The apparatus of claim 9, wherein the controller isolates the heater assembly from ground to pulse the RF floating voltage level of the heater assembly when the ICP power or voltage is first turned ON.

11. The apparatus of claim 9, wherein the controller isolates the heater assembly from ground to increase the RF floating voltage level of the heater assembly when the ICP power or voltage is first turned ON and gradually reduces the RF floating voltage level over a duration of an ICP power or voltage pulse.

12. An apparatus for heating a lid of a process chamber, comprising:
a heater assembly with a circular form and with a lowermost surface in contact with an uppermost surface of the lid of the process chamber, wherein the heater assembly has four resistive elements separately encased in conductive material, each forming one of four quadrants of the heater assembly and wherein an outer periphery of the heater assembly is electrically isolated from any ground of the process chamber by a gap of at least 0.35 inches; and
at least one RF voltage modulation controller connected to each of the quadrants and a ground, wherein the at least one RF voltage modulation controller is configured to automatically adjust an RF floating voltage level of at least one of the quadrants of the heater assembly.

13. The apparatus of claim 12, wherein the at least one RF voltage modulation controller comprises a switch with an OFF state and an ON state and wherein the at least one RF voltage modulation controller is configured to ground one or more of the quadrants of the heater assembly in the ON state and to disconnect from ground one or more of the quadrants of the heater assembly in the OFF state.

14. The apparatus of claim 12, wherein the at least one RF voltage modulation controller comprises a variable capacitor that is configured to be automatically adjusted to control the RF floating voltage level on at least one quadrant of the heater assembly.

15. The apparatus of claim 12, wherein the at least one RF voltage modulation controller comprises a set of solid-state capacitors configured to automatically adjust the RF floating voltage level on at least one quadrant of the heater assembly and wherein a total capacitive value of the set of solid-state capacitors can be adjusted by selecting and deselecting different solid-state capacitors within the set of solid-state capacitors.

16. The apparatus of claim 12, wherein each quadrant of the heater assembly is connected to adjacent quadrants by a nonconductive bridge to form a unitary heater assembly structure.

17. The apparatus of claim 12, wherein the at least one RF voltage modulation controller is connected to a controller and wherein the controller is configured to regulate the RF floating voltage level on at least one quadrant of the heater assembly in response to a level of inductive coupling plasma (ICP) power or voltage provided to ICP coils positioned above the heater assembly in the process chamber.

18. The apparatus of claim 17, wherein the controller isolates at least one quadrant from ground to pulse the RF floating voltage level of the at least one quadrant of the heater assembly when the ICP power or voltage is first turned ON.

19. The apparatus of claim 17, wherein the controller isolates at least one quadrant of the heater assembly from ground to increase the RF floating voltage level of at least one of the at least one quadrant when the ICP power or voltage is first turned ON and gradually reduces the RF floating voltage level over a duration of an ICP power or voltage pulse.

20. A heater assembly for a lid of a process chamber, comprising:
a circular structure with a lowermost surface configured to contact an uppermost surface of the lid when installed in the process chamber, wherein the circular structure has four resistive elements separately encased in conductive material, each forming a quadrant of the circular structure and wherein an outer periphery of the heater assembly is configured to be electrically isolated from any ground when installed in the process chamber by a gap of at least 0.35 inches.
